(19) United States
(12) Patent Application Publication
(10) Pub. No.: US 2025/0107397 A1
(43) Pub. Date: Mar. 27, 2025

(54) DISPLAY DEVICE, APPARATUS FOR MANUFACTURING THE DISPLAY DEVICE, AND METHOD OF MANUFACTURING THE DISPLAY DEVICE

(71) Applicant: SAMSUNG DISPLAY CO., LTD., YONGIN-SI (KR)

(72) Inventors: Ha Young CHOI, Yongin-si (KR); Moon Kon KIM, Yongin-si (KR); Hee Chang KIM, Yongin-si (KR); Ki Yol NAM, Yongin-si (KR); Min Hee PARK, Yongin-si (KR); Kyung Hoon CHAE, Yongin-si (KR)

(21) Appl. No.: 18/750,083

(22) Filed: Jun. 21, 2024

(30) Foreign Application Priority Data
Sep. 22, 2023 (KR) 10-2023-0127493

(51) Int. Cl. H10K 59/80; H10K 102/00

(52) U.S. Cl. CPC H10K 59/872; H10K 2102/311

(57) ABSTRACT

A display device includes a cover window, a display module disposed on the cover window and including a display panel, a driving board disposed on the display module and connected to the display panel, and an outer structure at least partially surrounding the display module and the driving board on the cover window. The outer structure is in contact with the driving board.

### CROSS-REFERENCE TO RELATED APPLICATION

This application claims priority under 35 U.S.C. § 119 to Korean Patent Application No. 10-2023-0127493, filed on Sep. 22, 2023, in the Korean Intellectual Property Office, the contents of which are herein incorporated by reference in its entirety.

### TECHNICAL FIELD

The present disclosure relates to a display device and, more specifically, to a display device, an apparatus for manufacturing the display device, and a method of manufacturing the display device.

### DISCUSSION OF THE RELATED ART

As the information society develops, demand for display devices for displaying images are increasing in various forms. Display devices may be flat panel display devices such as liquid crystal display (LCD) devices, field emission display devices, and light emitting display devices. The light emitting display devices may include an organic light emitting diode (OLED) display device including an organic light emitting diode (OLED) element as a light emitting element, and a light emitting diode display device including an inorganic light emitting diode element, such as a light emitting diode, as a light emitting element.

Flexible display devices having edge portions that are bent to have a predetermined curvature to have been introduced. Accordingly, cover windows for such display devices may also be bent to the predetermined curvature.

As the cost and difficulty of manufacturing a display device increases with the advancement of technology, a process of modularizing each component of the display device and assembling them individually is being actively used.

### SUMMARY

A display device includes a cover window, a display module disposed on the cover window and including a display panel, a driving board disposed on the display module and connected to the display panel, and an outer structure at least partially surrounding the display module and the driving board on the cover window. The outer structure is in contact with the driving board.

An inner surface of the outer structure may directly contact a side surface of the driving board.

A boundary of the inner surface of the outer structure may coincide with a boundary of a side surface of the driving board.

The outer structure may cover at least a portion of a lower surface of the driving board.

The outer structure may include a first portion in contact with the side surface of the driving board, and a second portion protruding from the first portion and in contact with the lower surface of the driving board.

The outer structure may overlap the display panel in the thickness direction of the display panel.

The display module may further include a cover spacer and/or a cover panel disposed between the display panel and the driving board.

The outer structure may overlap the cover spacer and/or the cover panel in the thickness direction of the display panel.

The display device may further include a middle frame at least partially surrounding the display module. The outer structure may be at least partially surrounded by the middle frame.

The middle frame may include a middle plate and a middle side wall disposed on a side surface of the middle plate. The outer structure may be at least partially surrounded by the middle side wall.

The middle side wall may include a first middle side wall connected to the middle plate and a second middle side wall connected to the first middle side wall. The first middle side wall may be disposed under the outer structure, and the second middle side wall may be disposed on the outside of the outer structure.

The display device may further include a first coupling disposed between the middle frame and the outer structure. The first coupling may include a first coupling element disposed between the first middle side wall and the outer structure, and a second coupling element disposed between the second middle side wall and the outer structure.

The display panel may include a main area, a bending area disposed on one side of the main area, and a sub-area disposed on one side of the bending area. The outer structure may include a first portion disposed on the outside of the bending area, and a second portion disposed on the inside of the bending area.

The outer structure may further include a third portion at least partially covering the sub-area of the display panel.

The display module may further include a bending protection layer disposed on the outside of the display panel in the bending area. The bending protection layer may extend to the sub-area.

One end of the bending protection layer may protrude more inwardly than one end of the third portion.

An apparatus for manufacturing a display device including a display module and a driving board connected to the display module includes an upper mold and a lower mold facing each other. An inner mold is disposed between the upper mold and the lower mold. The inner mold includes an outer wall, an inner wall disposed inside the outer wall, a cavity disposed between the outer wall and the inner wall, and an accommodation portion disposed inside the inner wall. The inner wall is in contact with the driving board.

A lower surface of the inner wall may be in contact with a lower surface of the driving board.

A method of manufacturing a display device including a display module and a driving board connected to the display module includes coupling a mold and the display device to one another. Paste is injected through an inlet of the mold. An outer structure is formed by curing the paste. The outer structure is in contact with the driving board.

An inner surface of the outer structure is in contact with a side surface of the driving board.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a front view illustrating an unfolded state of a display driving module according to an embodiment;

FIG. 3 is a rear view illustrating the unfolded state of the display driving module according to an embodiment;

FIG. 4 is a rear view illustrating a bent state of the display driving module according to an embodiment;

FIG. 5 is a schematic cross-sectional view taken along line X1-X1′ of FIG. 4;

FIG. 6 is a schematic cross-sectional view illustrating a stacked structure of a display module according to an embodiment;

FIG. 7 is a schematic rear view of a main body according to an embodiment;

FIG. 8 is a cross-sectional view taken along line X2-X2′ of FIG. 7;

FIG. 9 is an enlarged view of area A of FIG. 8;

FIG. 10 is an enlarged view of area B of FIG. 8;

FIG. 11 is a schematic rear view of a main body according to an embodiment;

FIG. 12 is a cross-sectional view taken along line X3-X3′ of FIG. 11;

FIG. 13 is an enlarged view of area C of FIG. 12;

FIG. 14 is a cross-sectional view of a main body according to an embodiment;

FIG. 15 is an enlarged view of area D of FIG. 14;

FIG. 16 is a flowchart illustrating a method of manufacturing a display device according to an embodiment;

FIG. 17 is a perspective view illustrating operation S100 of FIG. 16;

FIG. 18 is a cross-sectional view illustrating operation S100 of FIG. 16;

FIG. 19 is a cross-sectional view illustrating operation S200 of FIG. 16;

FIG. 20 is an enlarged view of area E of FIG. 19;

FIG. 21 is a cross-sectional view illustrating operation S300 of FIG. 16;

FIG. 22 is a cross-sectional view illustrating operation S400 of FIG. 16;

FIG. 23 is a cross-sectional view illustrating operation S500 of FIG. 16; and

FIG. 24 is a cross-sectional view illustrating operation S600 of FIG. 16.

### DETAILED DESCRIPTION

Embodiments of the present invention will now be described more fully hereinafter with reference to the accompanying drawings. This invention may, however, be embodied in different forms and should not necessarily be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers may indicate the same components throughout the specification and the drawings.

Hereinafter, embodiments of the present disclosure will be described in detail with reference to the accompanying drawings.

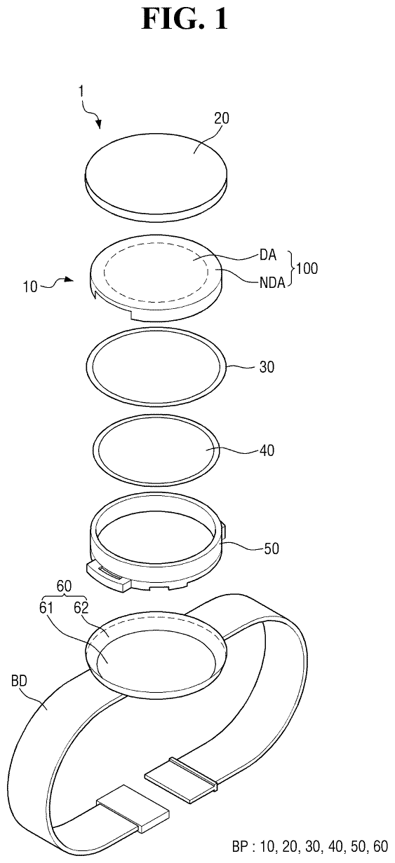

FIG. 1 is a perspective view of a display device according to an embodiment.

Referring to FIG. 1, a display device 1, according to the embodiment, may include a main body BP and a wearable portion BD. Although a smart watch is illustrated as an example of the display device 1 in the present specification, the present disclosure is not necessarily limited thereto. In an embodiment, the display device 1 may also be various display devices 1 such as a smartphone, a television, and a computer monitor.

The main body BP may include a display driving module 10 on which an image is displayed, a cover window 20, an outer structure 30, a coupling 40, a middle frame 50, and a bottom cover 60. In the main body BP, the bottom cover 60, the middle frame 50, the coupling 40, the outer structure 30, the display driving module 10, and the cover window 20 may be sequentially arranged. The cover window 20 may be considered to be the top of the arrangement.

The display driving module 10 may include a display panel 100. The display panel 100 may be a screen on which various information, content, user interface, etc. are displayed as images. The display panel 100 may be, but is not necessarily limited to, an organic light emitting diode (OLED) display panel or a liquid crystal display (LCD) panel. The display panel 100 may include a display area DA, where an image is displayed, and a non-display area NDA, disposed around the display area DA. As illustrated in FIG. 1, the display panel 100 may be generally circular in a plan view. However, the present disclosure is not necessarily limited thereto, and the display panel 100 may also have various shapes, for example, may have a polygonal shape, such as a quadrilateral, or an oval shape.

The cover window 20 may be disposed on the display driving module 10 to protect the display driving module 10. The cover window 20 may transmit light emitted from the display driving module 10. In some embodiments, the cover window 20 may include a light blocking portion to block some of the light emitted from the display driving module 10.

The cover window 20 may be made of a transparent plastic material, a glass material, or a tempered glass material. In an embodiment, the cover window 20 may be made of sapphire glass and/or a chemically strengthened glass, such as GORILLA GLASS developed and manufactured by Corning Inc., or may have a stacked structure thereof. In an embodiment, the cover window 20 may include polyethyleneterephthalate (PET), polycarbonate (PC), polyethersulfone (PES), polyethylenenaphthalate (PEN), and/or polynorbornene (PNB). The cover window 20 may be made of tempered glass in view of scratches and transparency.

The cover window 20 may overlap the display driving module 10 and cover a front surface of the display driving module 10. The cover window 20 may have a shape generally similar to the shape of the display driving module 10 in a plan view. However, the cover window 20 may be larger in size than the display driving module 10. For example, the cover window 20 may protrude further outward than the display driving module 10. The planar shape of the cover window 20 may be the same as the planar shape of the main body BP. For example, the cover window 20 may be generally circular in a plan view. However, the present disclosure is not necessarily limited thereto, and the cover window 20 may also have various shapes, for example, may have a polygonal shape, such as a quadrilateral, or an oval shape.

In some embodiments, as illustrated in the drawing, the cover window 20 may be a flat type window. For example, the cover window 20 may have a generally flat plate shape. However, the present disclosure is not necessarily limited thereto, and in an embodiment, the cover window 20 may be a three-dimensional window of a three-dimensional or dome type. In this case, the cover window 20 may include a central portion and a curved portion bent from the central portion.

The outer structure 30 may be disposed between the cover window 20 and the middle frame 50. The outer structure 30 may couple the display driving module 10, the cover window 20, the coupling 40, and the middle frame 50 together.

The outer structure 30 may be disposed along an edge of the display driving module 10. In some embodiments, the outer structure 30 may have a ring shape with a central hole in a plan view. For example, the outer structure 30 may have a donut shape or a ring shape in a plan view. In a plan view, the shape and size of the outer structure 30 may correspond to the shape and size of the cover window 20. For example, when the cover window 20 has a circular shape in a plan view, the outer structure 30 may also have a circular shape.

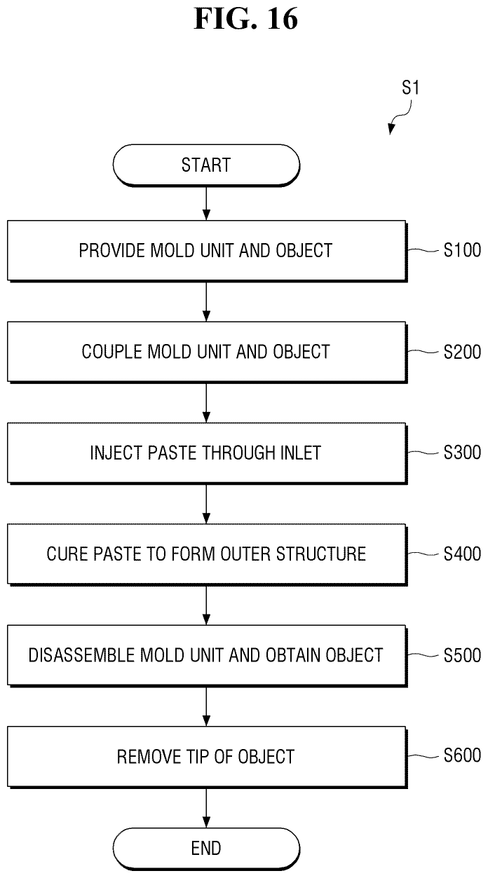

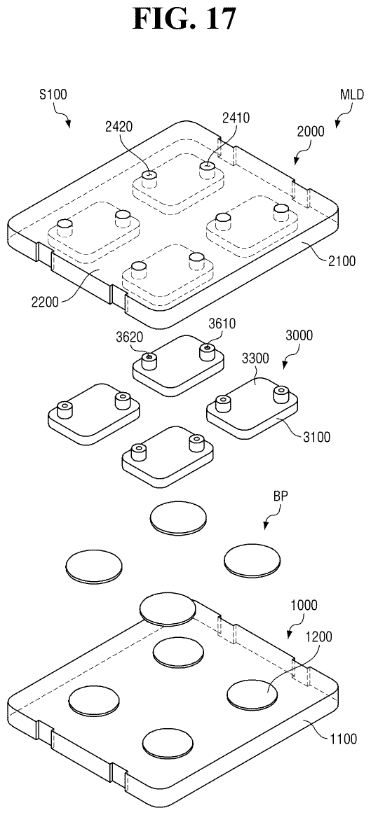

In some embodiments, the outer structure 30 may include a resin. For example, the outer structure 30 may be made of optical clear resin (OCR), but the present disclosure is not necessarily limited thereto. The outer structure 30 may be applied to the outside of the display driving module 10 in a liquid or paste state. For example, the outer structure 30 may be formed by injecting paste into a mold included in a mold MLD (see FIG. 17) which will be described later. Then, the outer structure 30 may be formed by curing the paste using ultraviolet rays or heat. The process of forming the outer structure 30 will be described later with reference to FIG. 16, etc.

The coupling 40 may be disposed between the outer structure 30 and the middle frame 50. The coupling 40 may bond the outer structure 30 and the middle frame 50 to each other. The coupling 40 may be an adhesive tape having an adhesive material applied to both sides and having a waterproof or dustproof function.

The coupling 40 may be disposed along the inner edge of the middle frame 50. In some embodiments, the coupling 40 may have a ring shape with a central hole in a plan view. For example, the coupling 40 may have a donut shape or a ring shape in a plan view. In a plan view, the shape and size of the coupling 40 may correspond to the shape and size of the middle frame 50. For example, when the middle frame 50 has a circular shape in a plan view, the coupling 40 may also have a circular shape.

The middle frame 50 may be disposed between the cover window 20 and the bottom cover 60. The middle frame 50 may be an intermediate coupling for coupling the cover window 20 and the bottom cover 60 together. For example, the middle frame 50 may include a bracket.

The bottom cover 60 may be disposed at the bottom of the main body BP. The bottom cover 60 may be disposed under the middle frame 50. The bottom cover 60 may be a housing coupled to the middle frame 50.

In some embodiments, the bottom cover 60 may include a central cover portion 61 and a peripheral portion 62.

The central cover portion 61 may be disposed in the center of the bottom cover 60 and may be generally flat. The central cover portion 61 may be an area corresponding to the cover window 20.

The peripheral portion 62 may be disposed around the central cover portion 61. The peripheral portion 62 may at least partially surround the central cover portion 61. The peripheral portion 62 may be a portion bent from the central cover portion 61. In some embodiments, a portion of the peripheral portion 62 may include a curved surface having a predetermined curvature, and the other portion may be flat. The degree (or angle) by which the peripheral portion 62 is bent from the central cover portion 61 may be an obtuse angle. However, the present disclosure is not necessarily limited thereto, and the degree (or angle) may also be a right angle or an acute angle.

The bottom cover 60 may be disposed on an outermost rear surface of the display device 1. The bottom cover 60 may include a plastic material, a metal and/or a glass material and may include a color coating layer. In an embodiment, the bottom cover 60 may be flat glass with a transparent, translucent, or opaque color coating layer.

In an embodiment, the bottom cover 60 may have the same shape as the cover window 20 and may include a glass material with a color coating layer. For example, the bottom cover 60, according to an example, may be symmetrical to the cover window 20 with respect to the middle frame 50 interposed between them and may include a transparent, translucent, or opaque color coating layer.

The wearable portion BD may be a portion for fixing the main body BP to a user's wrist or the like. For example, the wearable portion BD may be a strap, a chain, and/or a bracelet.

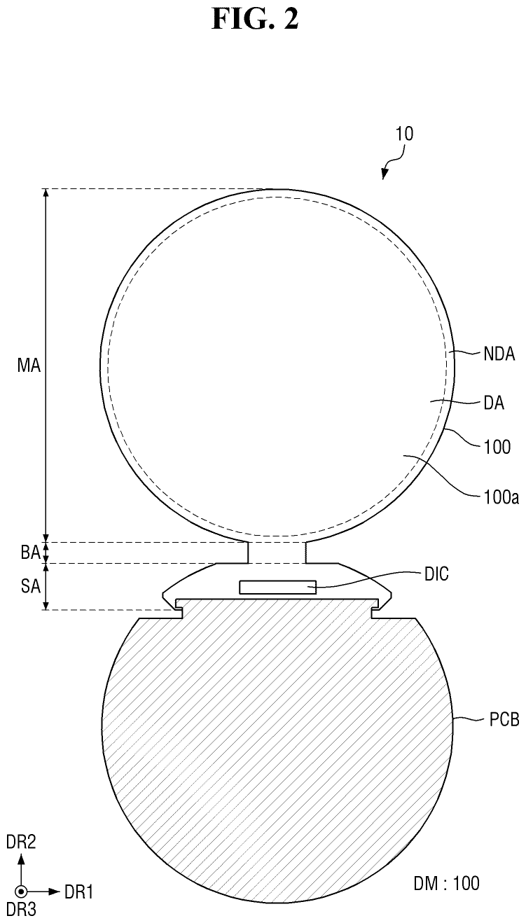

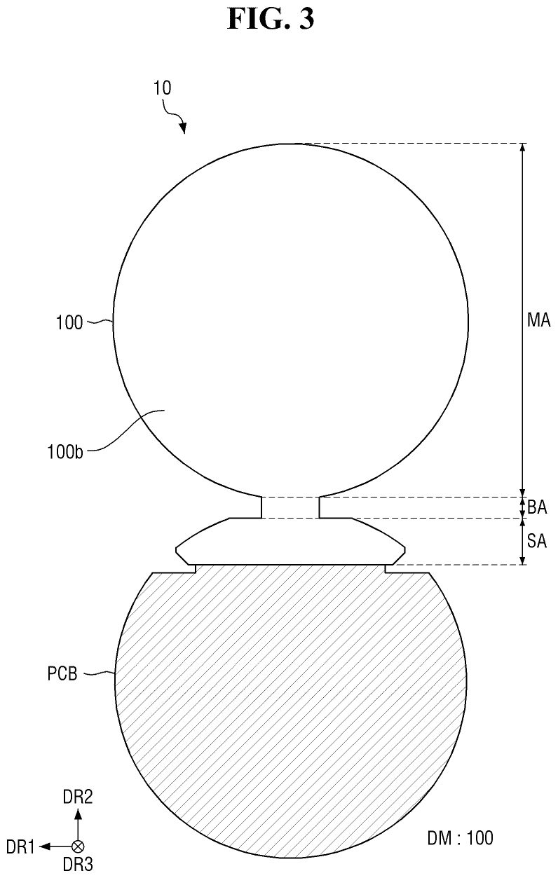

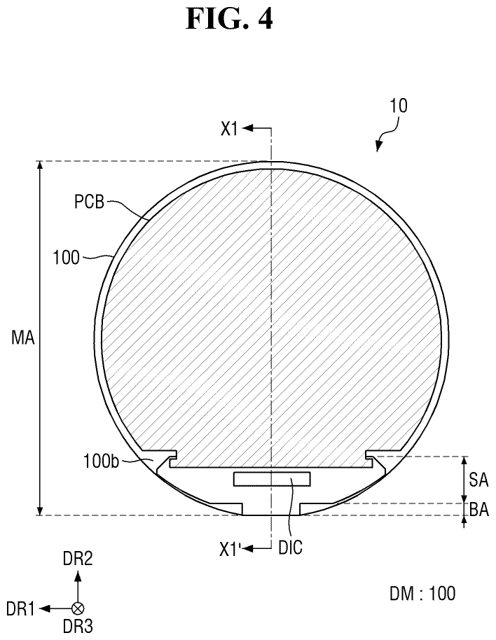

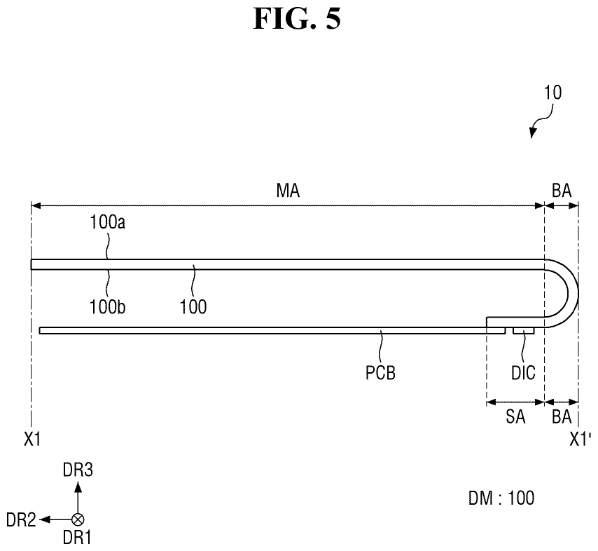

FIG. 2 is a front view illustrating an unfolded state of a display driving module according to an embodiment. FIG. 3 is a rear view illustrating the unfolded state of the display driving module according to an embodiment. FIG. 4 is a rear view illustrating a bent state of the display driving module according to an embodiment. FIG. 5 is a schematic cross-sectional view taken along line X1-X1′ of FIG. 4.

Referring to FIGS. 2 through 5, the display driving module 10 may include a display module DM, a driving chip DIC, and a driving board PCB.

The display module DM may include the display panel 100. Examples of the display panel 100 may include an organic light emitting diode (OLED) display panel, a micro light emitting diode (LED) display panel, a nano LED display panel, a quantum dot light emitting display panel, a liquid crystal display panel, a plasma display panel, a field emission display panel, an electrophoretic display panel, and an electrowetting display panel. A case where an organic light emitting diode (OLED) display panel is applied as an example of the display panel 100 will be described below, but the present disclosure is not necessarily limited to this case, and other display panels can also be applied as long as the same technical spirit is applicable.

The display panel 100 may include a display area DA and a non-display area NDA. The display area DA may refer to a portion that displays an image, and the non-display area NDA may refer to a portion that does not display an image.

The display area DA may have a circular shape in a plan view. However, the present disclosure is not necessarily limited thereto, and the display area DA may also have various shapes in a plan view, such as a rectangle or a rectangle with rounded corners, a square, other polygons, or an oval.

The non-display area NDA may be disposed around the display area DA. The non-display area NDA may be a bezel area. The non-display area NDA may at least partially surround the display area DA. However, the present disclosure is not necessarily limited thereto. For example, the non-display area NDA might not be disposed in at least a portion of the area around the display area DA.

Signal lines or driving circuits for transmitting signals to the display area DA (e.g., a display area or a touch area) may be disposed in the non-display area NDA. In an embodiment, the non-display area NDA may include a portion of the touch area, and a sensor such as a pressure sensor may be disposed in the portion.

The display panel 100 may include a plurality of pixels disposed in the display area DA. The pixels may be arranged in a matrix. Each of the pixels may be rectangular or square in a plan view. However, the present disclosure is not necessarily limited thereto, and each of the pixels may also have a rhombus shape with each side inclined with respect to a first direction DR1 or a second direction DR2. Each pixel may include an emission area. The shape of each emission area may be the same as or different from the shape of a corresponding pixel. For example, when a pixel has a rectangular shape, the emission area of the pixel may have various shapes such as a rectangle, a rhombus, a hexagon, an octagon, and a circle.

In the drawings, the first direction DR1 and the second direction DR2 are horizontal directions intersecting each other. For example, the first direction DR1 and the second direction DR2 may be orthogonal to each other. In addition, a third direction DR3 may be a vertical direction intersecting and, for example, orthogonal to the first direction DR1 and the second direction DR2. In the present specification, a direction indicated by an arrow of each of the first through third directions DR1 through DR3 may be referred to as a first side, and a direction opposite to the direction may be referred to as a second side.

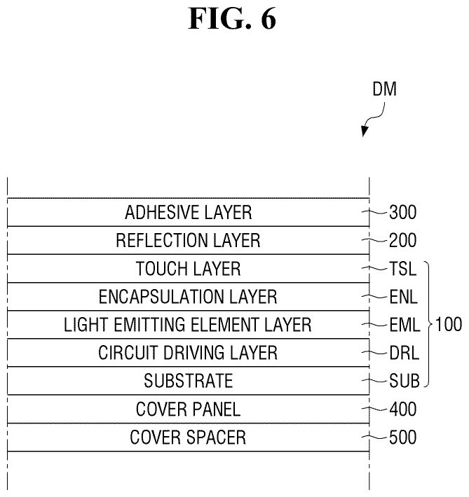

The display driving module 10 may further include a touch sensor that detects a touch input. The touch sensor may be provided on the display panel 100 in the form of a touch layer TSL (see FIG. 6). In this case, the touch layer TSL (see FIG. 6) may be provided integrally with the display panel 100. However, the present disclosure is not necessarily limited thereto, and the touch sensor may also be provided as a panel or film separate from the display panel 100 and attached onto the display panel 100. Although a case where the touch sensor is provided in the form of the touch layer TSL (see FIG. 6) is described in the following embodiments, the present disclosure is not necessarily limited thereto.

The touch area may be an area where a touch input is detected. The touch area may overlap the display area DA. For example, the display area DA may be an area where an image is displayed and a touch input is detected.

In some embodiments, the display panel 100 may include a flexible substrate including a flexible polymer material such as polyimide. Accordingly, the display panel 100 can be curved, bent, folded, or rolled.

The display panel 100 may include a main area MA, a bending area BA, and a sub-area SA. The bending area BA may be disposed between the main area MA and the sub-area SA in the second direction DR2. The main area MA may be disposed on a first side of the bending area BA in the second direction DR2. The sub-area SA may be disposed on a second side of the bending area BA in the second direction DR2.

The display area DA of the display panel 100 may be disposed within the main area MA. In an embodiment, an edge portion of the main area MA around the display area DA, the entire bending area BA, and the entire sub-area SA may be the non-display area NDA. However, the present disclosure is not necessarily limited thereto, and the bending area BA and/or the sub-area SA may also include the display area DA.

The main area MA may have a shape that is generally similar to the outer shape of the display driving module 10, in a plan view. The main area MA may be a flat area disposed in one plane. However, the present disclosure is not necessarily limited thereto, and at least a portion of an edge of the main area MA may be bent in the third direction DR3 to form a curved surface or may be bent in a vertical direction.

When at least a portion of the edge of the main area MA is bent in the third direction DR3 to form a curved surface or is bent in the vertical direction, the display area DA may also be disposed in the portion. However, the present disclosure is not necessarily limited thereto, and the curved surface or the bent portion of the edge may be a non-display area that does not display an image, or a display area and a non-display area may coexist in the portion.

The bending area BA may be connected to a second side of the main area MA in the second direction DR2. For example, the bending area BA may be connected to a lower short side of the main area MA. A width of the bending area BA, for example, in the first direction DR1 may be smaller than a width of the main area MA adjacent to the bending area BA, for example, a width of the main area MA in the first direction DR1. A connection portion between the main area MA and the bending area BA may have an L-cut shape.

The bending area BA may be an area where the display panel 100 is bent. As illustrated in FIGS. 4 and 5, in the bending area BA, the display panel 100 may be bent downward in a thickness direction to have a curvature. For example, the display panel 100 may be bent in the bending area BA toward a second side in the third direction DR3.

The bending area BA may have a constant radius of curvature. However, the present disclosure is not necessarily limited thereto, and the bending area BA may also have a different radius of curvature in each section. As the display panel 100 is bent in the bending area BA, the surface of the display panel 100 may be inverted. For example, as illustrated in FIG. 5, the display panel 100 may be bent in a direction opposite to a first surface 100a which is a display surface. Accordingly, of a second surface 100b opposite the display surface, the second surface 100b of the main area MA and the second surface 100b of the sub-area SA may face each other in the third direction DR3.

The sub-area SA may be disposed on the second side of the bending area BA in the second direction DR2. The sub-area SA may extend from the bending area BA. A width of the sub-area SA, for example, in the first direction DR1 may be greater than the width of the bending area BA, for example, in the first direction DR1. A connection portion between the sub-area SA and the bending area BA may have an L-cut shape.

In some embodiments, the sub-area SA may be smaller in size than the main area MA of the display panel 100. For example, as illustrated in FIG. 4, when the display panel 100 is bent, the sub-area SA may completely overlap the main area MA. When the display panel 100 is bent, an outer edge of the sub-area SA may be at least partially surrounded by an outer edge of the main area MA in a plan view. The outer edge of the sub-area SA may be disposed inside the outer edge of the main area MA in a plan view.

As illustrated in FIG. 5, when the display panel 100 is bent, the sub-area SA may be overlapped by the main area MA in the thickness direction of the display panel 100, for example, in the third direction DR3. The sub-area SA may be disposed under the main area MA in the third direction DR3.

The driving chip DIC may be disposed on the sub-area SA of the display panel 100. In some embodiments, the driving chip DIC may be disposed on the first surface 100a of the display panel 100 in the sub-area SA of the display panel 100. In an embodiment, as illustrated in the drawings, the driving chip DIC may be directly mounted on the display panel 100 using a chip on glass (COG) or chip on plastic (COP) method. In an embodiment, the driving chip DIC may be mounted on a flexible film using a chip on film (COF) method.

The driving chip DIC may generate and output data voltages, power voltages, scan timing signals, etc. The driving chip DIC may include an integrated circuit that drives the display panel 100. The integrated circuit may include an integrated circuit for a display and/or an integrated circuit for a touch sensor. However, the present disclosure is not necessarily limited thereto, and the integrated circuit for a display and the integrated circuit for a touch sensor may also be provided as separate chips or may be integrated into one chip.

The driving board PCB may be disposed on an end of the sub-area SA of the display panel 100. A pad may be disposed at the end of the sub-area SA of the display panel 100. The pad may include a plurality of display signal wiring pads and touch signal wiring pads. The driving board PCB may be connected to the pad at the end of the sub-area SA of the display panel 100. The driving board PCB may be attached onto the pad using a conductive adhesive such as an anisotropic conductive film or an anisotropic conductive adhesive. The driving board PCB may be a flexible printed circuit board or a flexible film such as a chip on film.

When the display panel 100 is bent, the driving chip DIC and the driving board PCB may be disposed opposite the display panel 100 of the main area MA with the display panel 100 of the sub-area SA interposed between them. For example, the driving chip DIC and the driving board PCB may be disposed on the first surface 100a of the sub-area SA and, as the display panel 100 is bent, may be disposed on a far side from the main area MA in the third direction DR3.

In some embodiments, the driving board PCB may be smaller in size than the main area MA of the display panel 100. For example, as illustrated in FIG. 4, when the display panel 100 is bent, the driving board PCB may completely overlap the main area MA of the display panel 100. When the display panel 100 is bent, an outer edge of the driving board PCB may be at least partially surrounded by the outer edge of the main area MA of the display panel 100 in a plan view. The outer edge of the driving board PCB may be disposed inside the outer edge of the main area MA of the display panel 100 in a plan view.

However, the present disclosure is not necessarily limited thereto, and in an embodiment, a part of the outer edge of the driving board PCB may coincide with a part of the outer edge of the display panel 100 or may be disposed outside the part of the outer edge of the display panel 100. In this case, the radius of the arc of the driving board PCB may be equal to or larger than the radius of the arc of the display panel 100.

The planar shape of the driving board PCB may be substantially similar to the planar shape of the display panel 100. For example, when the display panel 100 is circular in a plan view, at least a portion of the driving board PCB may be circular. However, the present disclosure is not necessarily limited thereto, and the shape of the driving board PCB can be variously changed.

FIG. 6 is a schematic cross-sectional view illustrating a stacked structure of a display module according to an embodiment.

Referring to FIG. 6, the display module DM may include a display panel 100, an anti-reflection layer 200, an adhesive layer 300, a cover panel 400, and a cover spacer 500. The display panel 100 may include a substrate SUB, a circuit driving layer DRL, a light emitting element layer EML, an encapsulation layer ENL, and a touch layer TSL.

The substrate SUB may support components disposed thereon. The substrate SUB may include a transparent material. For example, the substrate SUB may include a transparent insulating material such as glass or quartz. The substrate SUB may be a rigid substrate. However, the present disclosure is not necessarily limited thereto, and the substrate SUB may also include plastic such as polyimide and may have flexible characteristics so that it can be curved, bent, folded, or rolled to a noticeable degree without cracking or otherwise sustaining damage.

The circuit driving layer DRL may be disposed on a first surface, for example, an upper surface of the substrate SUB. The circuit driving layer DRL may include a circuit that drives the light emitting element layer EML of each pixel. The circuit driving layer DRL may include a plurality of thin-film transistors.

The light emitting element layer EML may be disposed on the circuit driving layer DRL. The light emitting element layer EML may include an organic light emitting layer. The light emitting element layer EML may emit light at various luminance levels according to a driving signal transmitted from the circuit driving layer DRL.

The encapsulation layer ENL may be disposed on the light emitting element layer EML. The encapsulation layer ENL may include an inorganic layer or a stacked layer of an inorganic layer and an organic layer. For example, the encapsulation layer ENL may include glass or an encapsulation film.

The touch layer TSL may be disposed on the encapsulation layer ENL. The touch layer TSL is a layer that recognizes a touch input and may perform the function of a touch sensor. The touch layer TSL may include a plurality of sensing areas and sensing electrodes.

The anti-reflection layer 200 may be disposed on the display panel 100. The anti-reflection layer 200 may reduce reflection of external light. The anti-reflection layer 200 may be a polarizing film. In this case, the anti-reflection layer 200 may polarize light that passes therethrough. However, the present disclosure is not necessarily limited thereto, and the anti-reflection layer 200 may also be a color filter layer. In this case, the anti-reflection layer 200 may include a color filter that selectively transmits light of a specific wavelength.

The adhesive layer 300 may be disposed on the anti-reflection layer 200. The adhesive layer 300 may bond the above-described cover window 20 (see FIG. 1) to the display panel 100 or the anti-reflection layer 200. In some embodiments, the adhesive layer 300 may be an optically clear adhesive (OCA) film or a pressure sensitive adhesive (PSA) film. Although the adhesive layer 300 is included in the display module DM in the drawing, the present disclosure is not necessarily limited thereto. For example, the adhesive layer 300 might not be included in the display module DM, but may be attached to the cover window 20 (see FIG. 1) and provided together with the cover window 20 (see FIG. 1).

The cover panel 400 may be disposed on a second surface, for example, a lower surface of the substrate SUB. The cover panel 400 may include at least one functional layer to perform a heat dissipation function, an electromagnetic wave shielding function, a buffer function, a strength reinforcing function, a support function, and/or a bonding function. For example, the functional layer of the cover panel 400 may be a sheet layer made of a sheet, a film layer made of a film, a thin-film layer, a coating layer, a panel, or a plate. One functional layer may be composed of a single layer or may be composed of a plurality of thin layers or coating layers that are stacked. The functional layer may be, for example, a support substrate, a heat dissipation layer, an electromagnetic wave shielding layer, a shock absorption layer, or a bonding layer.

The cover spacer 500 may be disposed on the cover panel 400. The cover spacer 500 may prevent the display driving module 10 from being bent by an external force or may reduce the degree of bending. The cover spacer 500 may keep the display driving module 10 relatively flat even when an external force is applied.

The cover spacer 500 may include a rigid or semi-rigid material. For example, the cover spacer 500 may include a metal such as stainless steel (SUS) or aluminum or include a polymer such as polymethylmethacrylate (PMMA), polycarbonate (PC), polyvinylalcohol (PVA), acrylonitrile-butadiene-styrene (ABS) or polyethylene terephthalate (PET).

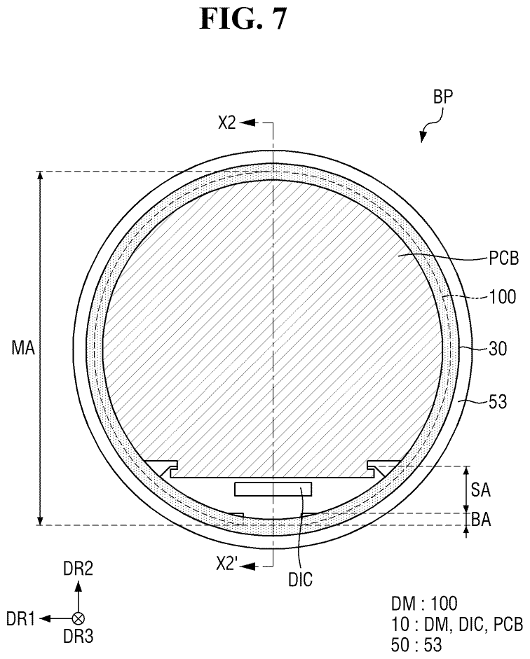

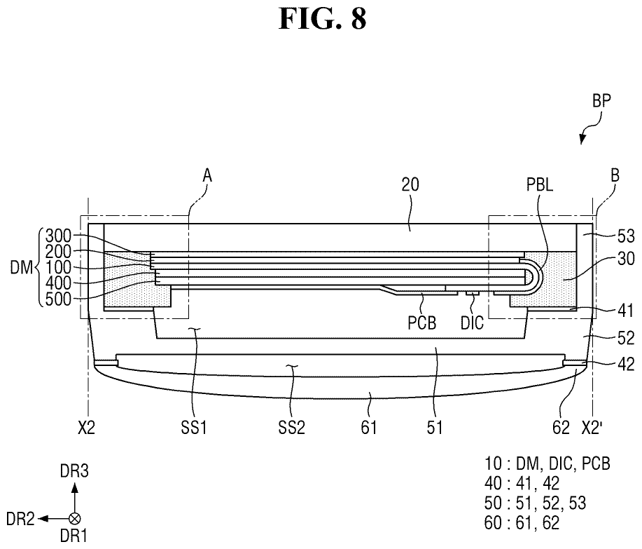

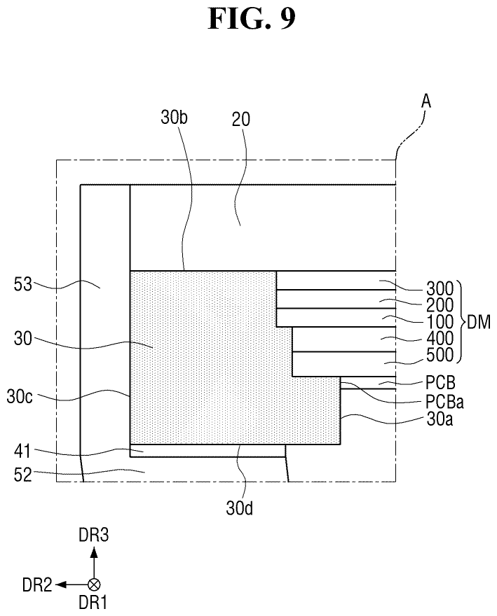

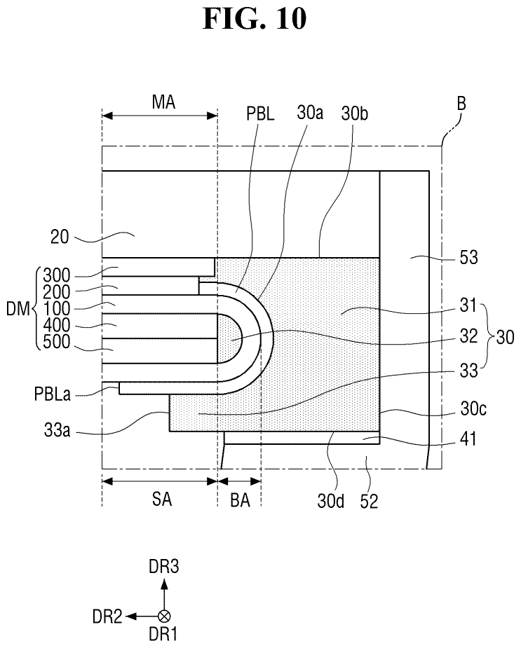

FIG. 7 is a schematic rear view of a main body, according to an embodiment. FIG. 8 is a cross-sectional view taken along line X2-X2′ of FIG. 7. FIG. 9 is an enlarged view of area A of FIG. 8. FIG. 10 is an enlarged view of area B of FIG. 8. FIG. 7 is a diagram of the main body BP viewed from the rear side, in which a middle plate 51 and a first middle side wall 52 of the middle frame 50 are omitted to more clearly explain the structure of the display driving module 10.

As described with reference to FIG. 1, the main body BP may include a display driving module 10, a cover window 20, an outer structure 30, a coupling 40, a middle frame 50, and a lower cover 60.

The display driving module 10 may include a display module DM, a driving chip DIC, and a driving board PCB as described above with reference to FIG. 2, etc. The display module DM may include a display panel 100, an anti-reflection layer 200, an adhesive layer 300, a cover panel 400, and a cover spacer 500 as described above with reference to FIG. 6.

The display module DM, the driving chip DIC and the driving board PCB of the display driving module 10 and the display panel 100, the anti-reflection layer 200, the adhesive layer 300, the cover panel 400 and cover spacer 500 of the display module DM have been described above, and thus to the extent that an element is not described in detail with respect to this figure, it may be understood that the element is at least similar to a corresponding element that has been described elsewhere within the present disclosure.

The cover spacer 500 may compensate for a height difference between a sub-area SA of the display panel 100 and the cover panel 400 and between the driving board PCB and the cover panel 400. For example, the cover spacer 500 may be disposed between the sub-area SA of the display panel 100 and the cover panel 400 and between the driving board PCB and the cover panel 400 in the third direction DR3. Accordingly, the display panel 100 and the driving board PCB may be kept flat. In some embodiments, the display panel 100 and the driving board PCB may be attached to the bottom of the cover spacer 500 through a separate adhesive. Accordingly, the display panel 100 and the driving board PCB may be kept fixed.

The display module DM may further include a bending protection layer PBL. The bending protection layer PBL may be disposed on an area of the display panel 100. In an embodiment, the bending protection layer PBL may be disposed on a bending area BA of the display panel 100. However, the present disclosure is not necessarily limited thereto, and the bending protection layer PBL may also be disposed on an area other than the bending area BA.

The bending protection layer PBL may be made of a polymer compound such as polyimide, acrylate, or epoxy. The bending protection layer PBL may minimize the generation of cracks due to stress applied to the display panel 100 when the display panel 100 is bent and may block the propagation of the cracks. Accordingly, the durability of the display module DM can be increased.

The cover window 20 may be attached to the display driving module 10 through the adhesive layer 300 of the display module DM. The size of the cover window 20 may be greater than the size of the display driving module 10. Accordingly, the cover window 20 may protrude further outward than the display driving module 10.

The outer structure 30 may be disposed between the cover window 20 and the middle frame 50 in the third direction DR3. As illustrated in FIG. 7, the outer structure 30 may at least partially surround the display driving module 10 in a plan view. As illustrated in FIG. 8, the outer structure 30 may at least partially surround the display driving module 10 in the horizontal direction defined by the first direction DR1 and the second direction DR2. As illustrated in FIG. 7, the outer structure 30 may be at least partially surrounded by a second middle side wall 53 of the middle frame 50 in a plan view. As illustrated in FIG. 8, the outer structure 30 may be at least partially surrounded by the second middle side wall 53 of the middle frame 50 in the horizontal direction defined by the first direction DR1 and the second direction DR2.

As illustrated in FIG. 8, the outer structure 30 may be disposed between the display driving module 10, the cover window 20, the coupling 40, and the middle frame 50. The outer structure 30 may couple the display driving module 10, the cover window 20, the coupling 40, and the middle frame 50 together.

As illustrated in FIG. 9, the outer structure 30 may be disposed within a space defined by an end of the display driving module 10 (e.g., end adjacent to the main area MA), a lower surface of the cover window 20, an inner surface of the second middle side wall 53, and an upper surface of a first coupling 41. For example, an inner surface 30a of the outer structure 30 may directly contact an outer edge of the display driving module 10, an upper surface 30b of the outer structure 30 may directly contact a lower surface of the cover window 20, an outer surface 30c of the outer structure 30 may directly contact an inner surface of the second middle side wall 53, and at least a portion of a lower surface 30d of the outer structure 30 may directly contact an upper surface of the first coupling 41.

In the display device 1, according to the current embodiment, at least a portion of the boundary of the inner surface 30a of the outer structure 30 may directly contact a side surface PCBa of the driving board PCB as illustrated in FIG. 9. For example, in a plan view, at least a portion of the boundary of the inner surface 30a of the outer structure 30 may coincide with the portion of the boundary corresponding to the arc of the driving board PCB as illustrated in FIG. 7.

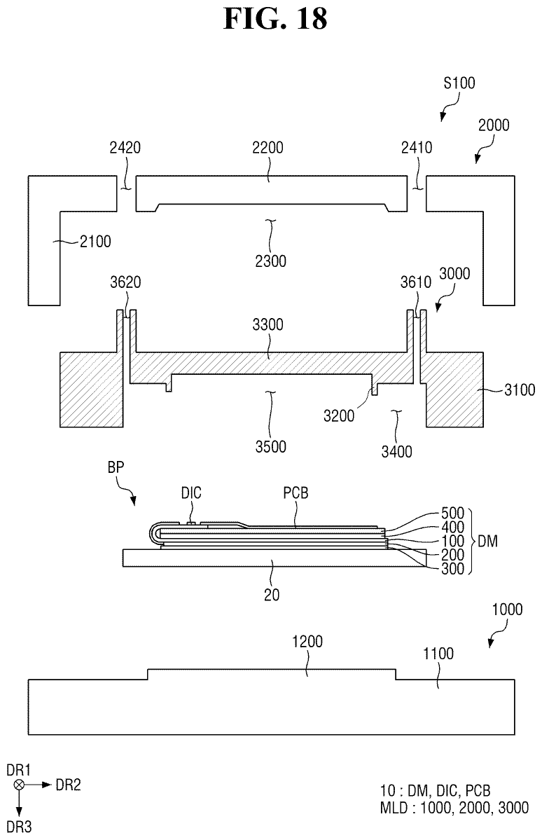

Accordingly, damage caused by pressing the display driving module 10 can be minimized. For example, as the inner surface 30a of the outer structure 30 directly contacts the side surface PCBa of the driving board PCB, in a display device manufacturing method S1 (see FIG. 16) to be described later, an inner wall 3200 (see FIG. 18) of an inner mold 3000 (see FIG. 18) of a mold MLD (see FIG. 17), the inner wall serving as sealing, may directly contact the driving board PCB. Accordingly, the inner wall 3200 (see FIG. 18) of the inner mold 3000 (see FIG. 18) might not contact the cover panel 400 or cover spacer 500 having relatively weak strength, but contact the driving board PCB having relatively strong strength, thereby minimizing damage due to the pressing of the display driving module 10. This will be described in detail later through the display device manufacturing method S1 with reference to FIG. 16, etc.

As illustrated in FIG. 10, the outer structure 30 may be disposed in a space defined by the other end of the display driving module 10 (e.g., the end adjacent to the bending area BA), the lower surface of the cover window 20, inner surface of the second middle side wall 53, and the upper surface of the first coupling 41. For example, the inner surface 30a of the outer structure 30 may be in direct contact with the outer edge of the display driving module 10 adjacent to the bending area BA, the upper surface 30b of the outer structure 30 may be in direct contact with the lower surface of the cover window 20, the outer surface 30c of the outer structure 30 may be in direct contact with the inner surface of the second middle side wall 53, and at least a portion of the lower surface 30d of the outer structure 30 may be in direct contact with the upper surface of the first coupling 41.

Although only both ends of the display driving module 10 are illustrated in the drawings, as described above, the outer structure 30 may be disposed in a space defined by the outer edge of the display driving module 10, the lower surface of the cover window 20, the inner surface of the second middle side wall 53, and the upper surface of the first coupling 41. Accordingly, in a plan view, the outer structure 30 may have a ring shape with a hole in the center, for example, a donut shape or a ring shape.

In the display device 1, according to the current embodiment, since the outer structure 30 is disposed in the space defined by the outer edge of the display driving module 10, the lower surface of the cover window 20, the inner surface of the second middle side wall 53, and the upper surface of the first coupling 41, an attachment area of the first coupling 41 may increase, thereby increasing the adhesion between the middle frame 50 and the cover window 20. Accordingly, since a sufficient attachment surface of the first coupling 41 can be secured by the outer structure 30, an attachment tolerance for coupling the cover window 20 and the middle frame 50 together can be minimized. Therefore, dead space between the middle frame 50 and the display driving module 10 can be minimized. In addition, since the outer structure 30 having a certain level of elasticity and strength is formed in the space defined by the outer edge of the display driving module 10, the lower surface of the cover window 20, the inner surface of the second middle side wall 53, and the upper surface of the first coupling 41, the impact resistance of the display device 1 can be increased.

In some embodiments, the outer structure 30 may include a first portion 31, a second portion 32, and a third portion 33.

The first portion 31 may be disposed outside the outer edge of the display driving module 10. For example, the first portion 31 may be in direct contact with the outer surface of the bending protection layer PBL, the lower surface of the cover window 20, the inner surface of the second middle side wall 53, and the upper surface of the first coupling 41.

The second portion 32 may be disposed inside the bending area BA of the display panel 100. For example, the second portion 32 may directly contact a back surface of the display panel 100, a side surface of the cover panel 400, and a side surface of the cover spacer 500 in the bending area BA of the display panel 100. In an embodiment, the second portion 32 fill the entire space formed by the bending area BA. The second portion 32 may keep the display panel 100 bent.

The third portion 33 may overlap the sub-area SA of the display panel 100. The third portion 33 may cover the sub-area SA of the display panel 100. The third portion 33 may cover a back surface of the display driving module 10. The third portion 33 may be in direct contact with the bending protection layer PBL.

In some embodiments, one end PBLa of the bending protection layer PBL may protrude further inward than one end 33a of the third portion 33. Accordingly, damage caused by pressing the display driving module 10 can be minimized. For example, in the display device manufacturing method S1 (see FIG. 16) to be described later, since an inner wall 3200 (see FIG. 18) of an inner mold 3000 (see FIG. 18) does not contact the cover panel 400 or the cover spacer 500 having a relatively weak strength and contacts the bending protection layer PBL having a relatively strong strength, damage caused by pressing the display driving module 10 can be minimized.

The coupling 40 may include the first coupling 41 and a second coupling 42. The coupling 40 may be an adhesive tape having an adhesive material applied to both sides and having a waterproof or dustproof function. The first coupling 41 and the second coupling 42 may include the same material, but the present disclosure is not necessarily limited thereto.

The first coupling 41 may be disposed on the upper surface of the middle frame 50, for example, an upper surface of the first middle side wall 52. The first coupling 41 may be disposed between the middle frame 50 and the outer structure 30 in the third direction DR3. For example, the first coupling 41 may couple an upper surface of the first middle side wall 52 of the middle frame 50 to a lower surface 30d of the outer structure 30. The first coupling 41 may be in direct contact with the outer structure 30.

The second coupling 42 may be disposed on a lower surface of the middle frame 50. The second coupling 42 may be disposed between the middle frame 50 and the bottom cover 60 in the third direction DR3. For example, the second coupling 42 may couple a lower surface of the first middle side wall 52 of the middle frame 50 to an upper surface of a peripheral portion 62 of the bottom cover 60.

The middle frame 50 may serve as a bracket for fixing the cover window 20 and the bottom cover 60 to each other.

The display driving module 10 may be disposed between the middle frame 50 and the cover window 20. The upper surface of the middle frame 50 may face a lower surface of the display driving module 10. The upper surface of the middle frame 50 may be spaced apart from the lower surface of the display driving module 10. A first storage space SS1 may be formed between the upper surface of the middle frame 50 and the lower surface of the display driving module 10. The first storage space SS1 may provide a space for storing peripheral circuits of an electronic device, such as a host driving system, a memory, and a battery.

In some embodiments, the middle frame 50 may include a middle plate 51, the first middle side wall 52 and the second middle side wall 53.

The middle plate 51 may be disposed under the display driving module 10. In the first storage space SS1 formed between an upper surface of the middle plate 51 and the lower surface of the display driving module 10, there may be at least one open portion through which a cable for electrical connection between a display driving circuit connected to the display driving module 10 and a host driving system passes and at least one concave portion in which various electronic circuit components mounted on an electronic device are disposed.

The first middle side wall 52 may be disposed on a side surface of the middle plate 51. A direction in which the first middle side wall 52 extends may be different from a direction in which the middle plate 51 extends. The first middle side wall 52 may support the outer structure 30. For example, the first middle side wall 52 may be coupled to the outer structure 30 through the first coupling 41. Accordingly, the waterproof performance of the display device 1 can be increased, and the penetration of foreign substances can be prevented.

The second middle side wall 53 may extend from the first middle side wall 52. The second middle side wall 53 may extend in the third direction DR3. The second middle side wall 53 may at least partially surround the outer surface of the outer structure 30 and the side surface of the cover window 20. The second middle side wall 53 may be in contact with an outer surface 30c of the outer structure 30 and the side surface of the cover window 20.

The bottom cover 60 may be disposed under the middle frame 50. For example, the upper surface of the bottom cover 60 may face a lower surface of the middle frame 50. At least a portion of the upper surface of the bottom cover 60 may be spaced apart from at least a portion of the lower surface of the middle frame 50. A second storage space SS2 may be formed between at least a portion of the upper surface of the bottom cover 60 and at least a portion of the lower surface of the middle frame 50. The second storage space SS2 may provide a space for storing peripheral circuits of an electronic device which are not placed in the first storage space SS1.

In some embodiments, the bottom cover 60 may include a central cover portion 61 and the peripheral portion 62.

The central cover portion 61 may be disposed under the middle plate 51. Peripheral circuits of an electronic device which are not placed in the first storage space SS1 may be placed in the second storage space SS2 formed between an upper surface of the central cover portion 61 and a lower surface of the middle plate 51. In some embodiments, a battery for operating the display device 1 may be placed in the second storage space SS2.

The peripheral portion 62 may be disposed on a side surface of the central cover portion 61. A direction in which the peripheral portion 62 extends may be different from a direction in which the central cover portion 61 extends. The peripheral portion 62 may be supported by the first middle side wall 52. In an embodiment, the peripheral portion 62 may be coupled to the first middle side wall 52 through the second coupling 42. Accordingly, the waterproof performance of the display device 1 can be increased, and the penetration of foreign substances can be prevented.

In an embodiment, the bottom cover 60 may be removably coupled to the first middle side wall 52. For example, the second coupling 42 between the first middle side wall 52 and the peripheral portion 62 may be omitted, and mechanical coupling may be adopted. In this case, a battery can be easily replaced after battery discharge during the use of the display device 1, and the display device 1 can be easily disassembled for repair.

Embodiments of the display device will now be described. In the following embodiments, the same elements as those of the embodiment described above may be indicated by the same reference characters, and to the extent that an element is not described in detail with respect to this figure, it may be understood that the element is at least similar to a corresponding element that has been described elsewhere within the present disclosure.

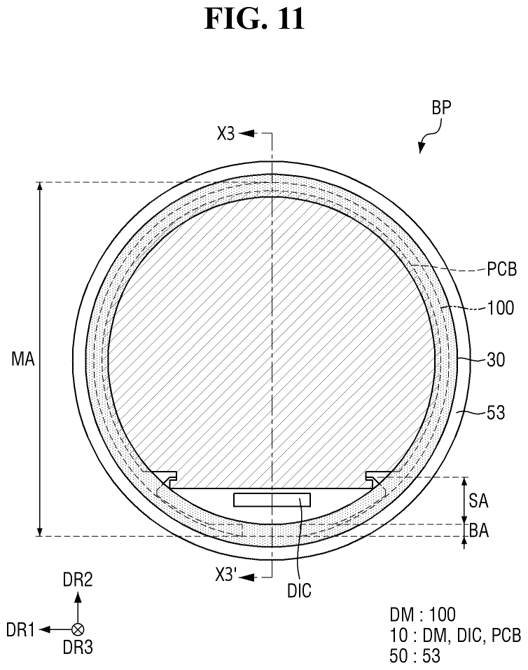

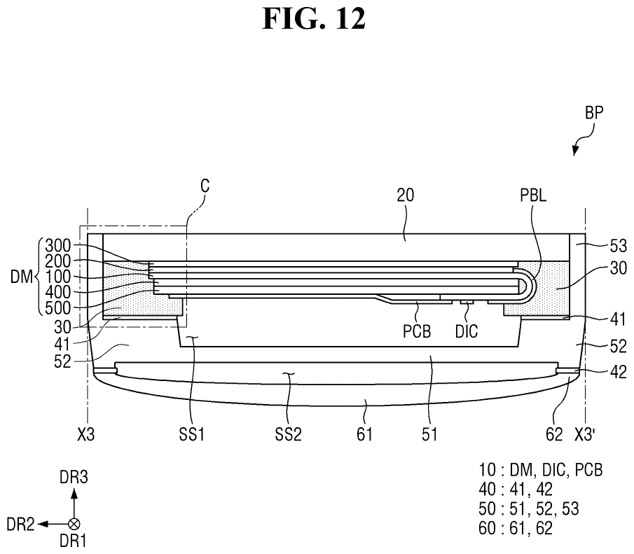

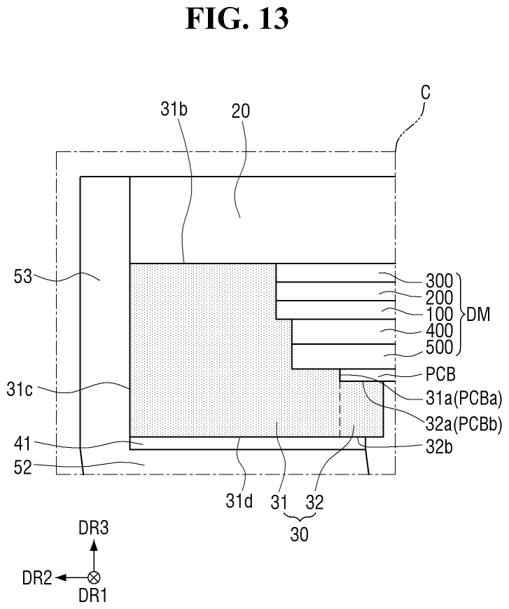

FIG. 11 is a schematic rear view of a main body according to an embodiment. FIG. 12 is a cross-sectional view taken along line X3-X3′ of FIG. 11. FIG. 13 is an enlarged view of area C of FIG. 12. FIG. 11 is a drawing of the main body BP viewed from the rear side, in which the middle plate 51 and the first middle side wall 52 of the middle frame 50 are omitted to explain the structure of the display driving module 10.

Referring to FIGS. 11 to 13, a display device 1, according to the current embodiment, is different from the display device 1, according to the embodiment described with reference to FIG. 7, etc., in that an outer structure 30 overlaps the driving board PCB in the third direction DR3.

For example, in the display device 1 according to the current embodiment, the outer structure 30 may include a first portion 31 and a second portion 32.

The first portion 31 may be disposed outside the outer edge of the display driving module 10. For example, an inner surface 31a of the first portion 31 may be in direct contact with the outer edge of the display driving module 10, an upper surface 31b of the first portion 31 may be in direct contact with the lower surface of the cover window 20, an outer surface 31c of the first portion 31 may be in direct contact with the inner surface of the second middle side wall 53, and a lower surface 31d of the first portion 31 may be in direct contact with the upper surface of the first coupling 41. In the display device 1, according to the current embodiment, as illustrated in FIG. 13, at least a portion of the inner surface 31a of the first portion 31 may be in direct contact with the side surface PCBa of the driving board PCB.

The second portion 32 may be disposed on a first side of the first portion 31. The second portion 32 may be disposed on the inner surface 31a of the first portion 31. For example, the second portion 32 may protrude from at least a portion of the inner surface 31a of the first portion 31.

The second portion 32 may be disposed on the driving board PCB. In some embodiments, the second portion 32 may be disposed between the driving board PCB and the first coupling 41 (or the first middle side wall 52) in the third direction DR3. For example, an upper surface 32a of the second portion 32 may be in contact with a lower surface PCBb of the driving board PCB, and a lower surface 32b of the second portion 32 may be in contact with the upper surface of the first coupling 41.

In the display device 1 of the current embodiment, as illustrated in FIGS. 11 to 13, the outer structure 30 may overlap the driving board PCB in the third direction DR3. The outer structure 30 may cover at least a portion of the lower surface PCBb of the driving board PCB. For example, as illustrated in FIG. 13, the second portion 32 may overlap the driving board PCB in the third direction DR3. The second portion 32 may cover at least a portion of the lower surface PCBb of the driving board PCB.

In addition, as illustrated in FIG. 11, at least a portion of the boundary of the side surface PCBa of the driving board PCB may protrude further outward than at least a portion of the boundary of the inner surface 30a of the outer structure 30 in a plan view. For example, the boundary of the portion corresponding to an arc of the driving board PCB may be disposed outside at least a portion of the boundary of the inner surface 30a of the outer structure 30 in a plan view. Accordingly, at least a portion of the driving board PCB may overlap the outer structure 30 in the third direction DR3.

Accordingly, damage caused by pressing the display driving module 10 can be minimized. For example, as the second portion 32 covers at least a portion of the lower surface PCBb of the driving board PCB, in a display device manufacturing method S1 (see FIG. 16) to be described later, an inner mold 3000 (see FIG. 18) may be in direct contact with the driving board PCB. Accordingly, the inner wall 3200 (see FIG. 18) of the inner mold 3000 (see FIG. 18) might not contact the cover panel 400 or cover spacer 500 having relatively weak strength, but contact the driving board PCB having relatively strong strength, thereby minimizing damage due to the pressing of the display driving module 10.

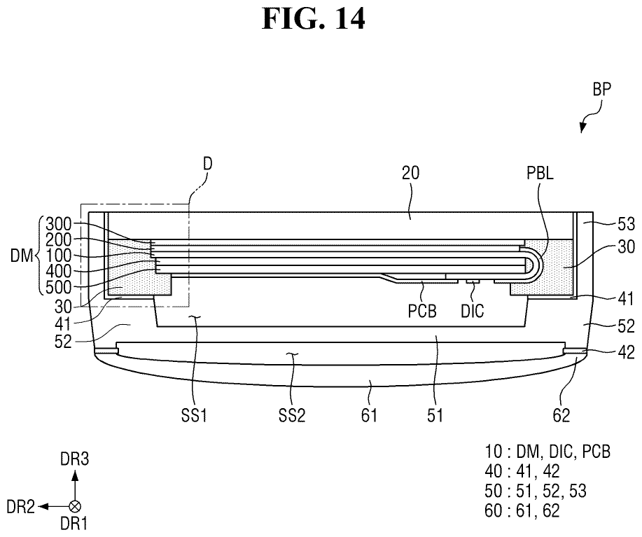

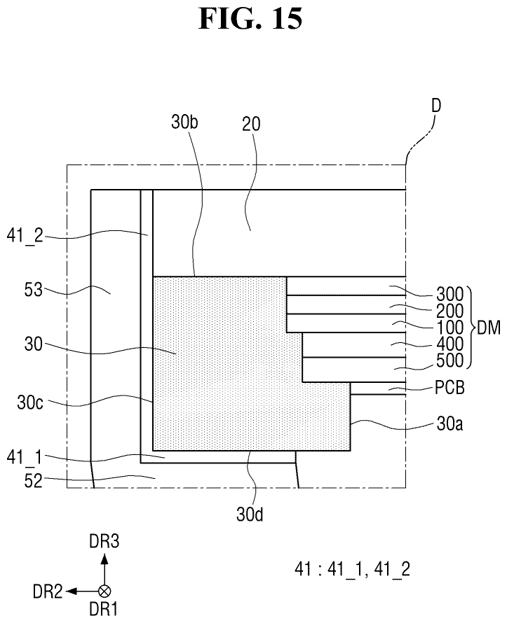

FIG. 14 is a cross-sectional view of a main body according to an embodiment. FIG. 15 is an enlarged view of area D of FIG. 14.

Referring to FIGS. 14 and 15, the display device 1, according to the current embodiments, is different from the display device 1 according to the embodiments described above with reference to FIGS. 7 and 11, etc. in that the first coupling 41 includes a first coupling element 41_1 and a second coupling element 41_2.

For example, the first coupling 41 may include the first coupling element 41_1 and the second coupling element 41_2.

The first coupling element 41_1 may be disposed on the upper surface of the middle frame 50, for example, on the upper surface of the first middle side wall 52. The first coupling element 41_1 may be disposed between the middle frame 50 and the outer structure 30 in the third direction DR3. For example, the first coupling element 41_1 may couple the upper surface of the first middle side wall 52 of the middle frame 50 and the lower surface 30d of the outer structure 30. The first coupling element 41_1 may be in direct contact with the lower surface 30d of the outer structure 30. In one embodiment, the first coupling element 41_1 may extend in a horizontal direction defined by the first direction DR1 and the second direction DR2.

The second coupling element 41_2 may be disposed on the inner surface of the second middle side wall 53. The second coupling element 41_2 may be disposed between the middle frame 50 and the outer structure 30, and between the middle frame 50 and the cover window 20, in the horizontal direction defined by the first direction DR1 and the second direction DR2. For example, the second coupling element 41_2 may couple a portion of the inner surface of the second middle side wall 53 and the outer surface 30c of the outer structure 30, and couple a portion of the inner surface of the second middle side wall 53 and the side surface of the cover window 20, in the horizontal direction defined by the first direction DR1 and the second direction DR2. In one embodiment, the second coupling element 41_2 may extend in a different direction from the first coupling element 41_1. For example, the second coupling element 41_2 may extend in the third direction DR3.

In the display device 1, according to the current embodiment, since the first coupling 41 further includes the second coupling element 41_2, adhesion between the display driving module 10, the cover window 20, the outer structure 30, and the middle frame 50 can be increased. Accordingly, the durability of the display device 1 can be increased.

Hereinafter, an apparatus for manufacturing a display device according to an embodiment and a method of manufacturing a display device according to an embodiment will be described. For case of description, an apparatus and method for manufacturing the display device according to an embodiment described with reference to FIG. 7, etc. will be described below as an example.

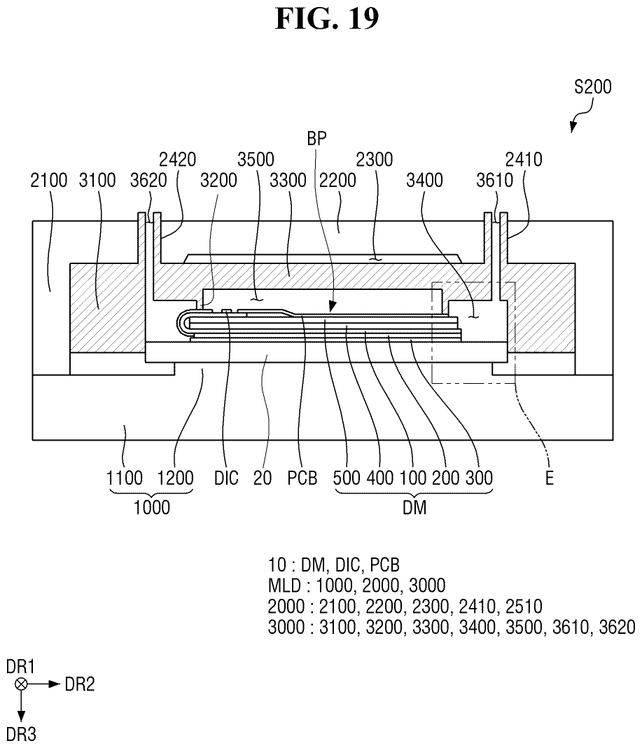

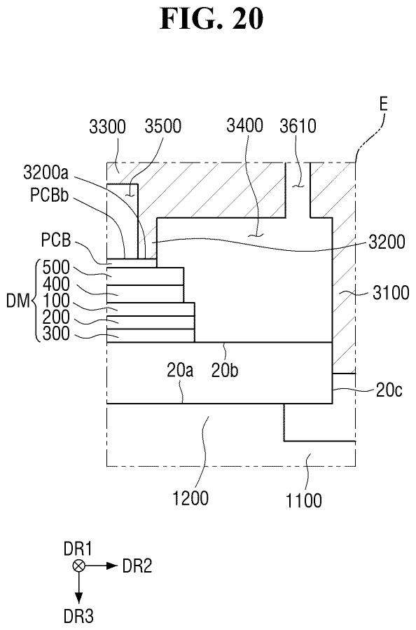

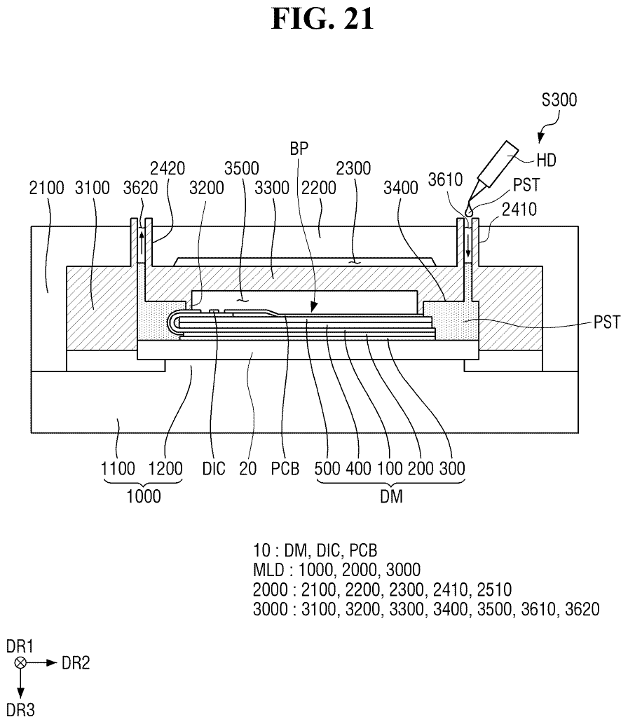

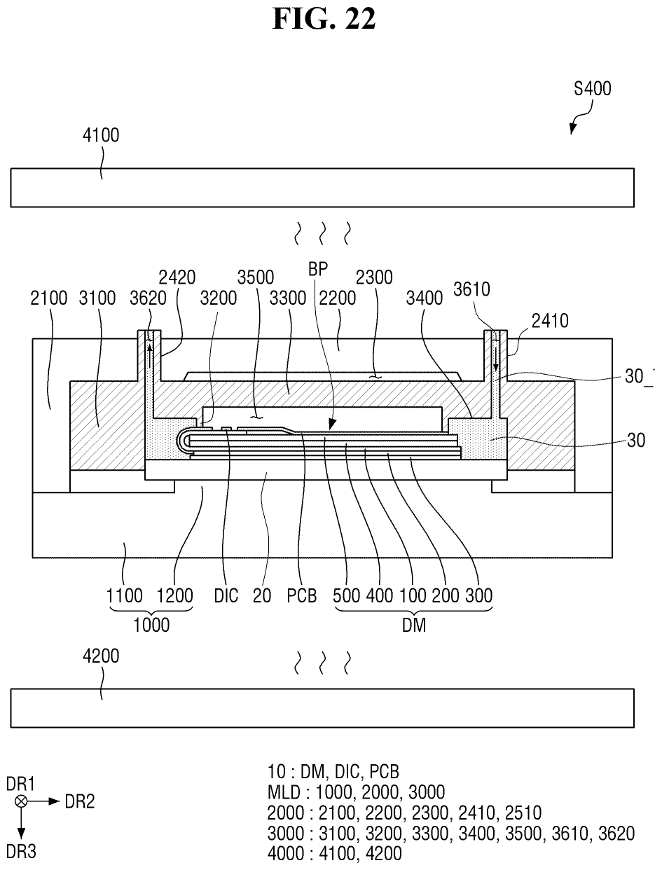

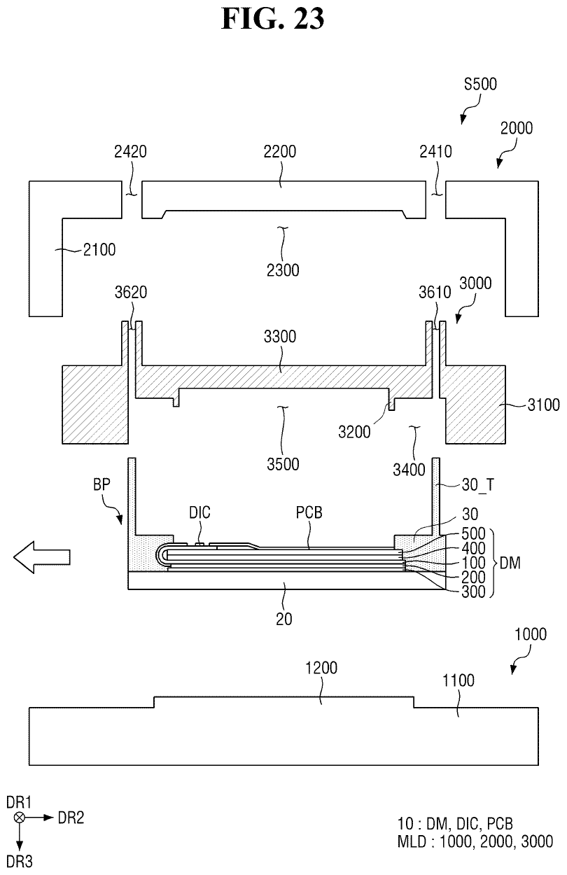

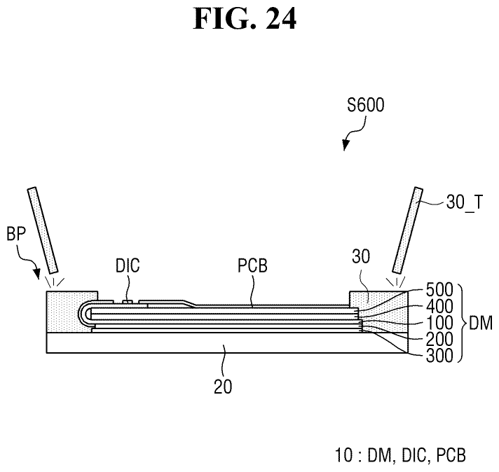

FIG. 16 is a flowchart illustrating a method of manufacturing a display device according to an embodiment. FIG. 17 is a perspective view illustrating operation S100 of FIG. 16. FIG. 18 is a cross-sectional view illustrating operation S100 of FIG. 16. FIG. 19 is a cross-sectional view illustrating operation S200 of FIG. 16. FIG. 20 is an enlarged view of area E of FIG. 19. FIG. 21 is a cross-sectional view illustrating operation S300 of FIG. 16. FIG. 22 is a cross-sectional view illustrating operation S400 of FIG. 16. FIG. 23 is a cross-sectional view illustrating operation S500 of FIG. 16. FIG. 24 is a cross-sectional view illustrating operation S600 of FIG. 16.

Referring to FIGS. 16 through 24, the display device manufacturing method S1, according to the embodiment, may include providing a mold and an object (operation S100), coupling the mold and the object together (operation S200), injecting paste through an inlet (operation S300), forming an outer structure by curing the paste (operation S400), disassembling the mold and collecting the object (operation S500), and removing a tip of the object (operation S600).

As illustrated in FIGS. 17 and 18, in the providing of the mold and the object (operation S100), a mold MLD and objects may be provided.

Each of the objects may be the main body BP of the display device 1 described above with reference to FIG. 1, etc. The main body BP, which is an object in the display device manufacturing method S1 according to the current embodiment, may be in a state in which a display driving module 10 and a cover window 20 are coupled to each other.

The mold MLD may be a display device manufacturing apparatus for forming an outer structure 30. The mold MLD may include a lower mold 1000, an upper mold 2000, and inner molds 3000.

The lower mold 1000 may be disposed under the main body BP which are the objects. The lower mold 1000 may include a base 1100 and mounting portions 1200.

The base 1100 may form the body of the lower mold 1000. The area of the base 1100 may be larger than the area of the objects. Although four objects are mounted on the base 1100 in the drawings, the present disclosure is not necessarily limited thereto. The area of the base 1100 may vary according to the number of objects mounted on the base 110.

The mounting portions 1200 may be disposed on the base 1100. The mounting portions 1200 may be portions that protrude from the base 1100 in the third direction DR3. The mounting portions 1200 and the base 1100 may be physically one component, but the present disclosure is not necessarily limited thereto. Although four mounting portions 1200 are disposed on the base 1100 in the drawings, the present disclosure is not necessarily limited thereto. The number of mounting portions 1200 disposed on the base 1100 may vary according to the number of objects mounted on the base 1100. In addition, although each of the mounting portions 1200 is smaller than the cover window 20 in the drawings, the present disclosure is not necessarily limited thereto. Each of the mounting portions 1200 may also be equal to or larger than in size than the cover window 20.

The upper mold 2000 may be disposed on the lower mold 1000. The upper mold 2000 may be disposed on the main bodies BP which are the objects. The upper mold 2000 may include first outer walls 2100, a first top plate 2200, first accommodation portions 2300, first coupling holes 2410, and second coupling holes 2420.

The first outer walls 2100 and the first top plate 2200 may form the body of the upper mold 2000. The outer shape of the upper mold 2000 defined by the first outer walls 2100 and the first top plate 2200 may roughly correspond to the outer shape of the base 1100 of the lower mold 1000, but the present disclosure is not necessarily limited thereto.

Each of the first accommodation portions 2300 may be a space at least partially surrounded by the first outer walls 2100 and the first top plate 2200. Each of the first accommodation portions 2300 may provide a space for accommodating an inner mold 3000. Although four first accommodation portions 2300 are illustrated in FIG. 17 as an example, the present disclosure is not necessarily limited thereto. For ease of description, a case where there is only one first accommodation portion 2300 will be described as an example in FIGS. 18 through 24 and in the following description.

The first coupling holes 2410 and the second coupling holes 2420 may be disposed in the first top plate 2200. The first coupling holes 2410 and the second coupling holes 2420 may be through holes penetrating upper and lower surfaces of the first top plate 2200. Each of the first coupling holes 2410 may be a hole to which an inlet 3610 of an inner mold 3000 is coupled, and each of the second coupling holes 2420 may be a hole to which an outlet 3620 of the inner mold 3000 is coupled.

In some embodiments, the lower mold 1000 and the upper mold 2000 may include stainless steel (SUS) and/or aluminum (Al), but the present disclosure is not necessarily limited thereto.

The inner molds 3000 may be disposed between the lower mold 1000 and the upper mold 2000. The inner molds 3000 may be additional molds disposed between the lower mold 1000 and the upper mold 2000 to more accurately seal the objects. Each of the inner molds 3000 may include second outer walls 3100, inner walls 3200, a second top plate 3300, a cavity 3400, a second accommodation portion 3500, an inlet 3610, and an outlet 3620.

The second outer walls 3100 and the second top plate 3300 may form the body of each inner mold 3000. The outer shape of each inner mold 3000 defined by the second outer walls 3100 and the second top plate 3300 may roughly correspond to the outer shape of a first accommodation portion 2300 of the upper mold 2000, but the present disclosure is not necessarily limited thereto.

The inner walls 3200 may be disposed inside the second outer walls 3100. The inner walls 3200 may be at least partially surrounded by the second outer walls 3100. The inner walls 3200 may be partition walls for isolating the cavity 3400 and the second accommodation portion 3500. The inner walls 3200 may extend substantially in the third direction DR3. However, the present disclosure is not necessarily limited thereto, and the inner walls 3200 may also extend in a diagonal direction.

The cavity 3400 may be disposed between the second outer walls 3100 and the inner walls 3200. The cavity 3400 may be a space at least partially surrounded by the second outer walls 3100, the inner walls 3200, and the second top plate 3300. The cavity 3400 may provide a space for forming the outer structure 30.

The second accommodation portion 3500 may be disposed inside the inner walls 3200. The second accommodation portion 3500 may be a space at least partially surrounded by the inner walls 3200 and the second top plate 3300. In a state in which the mold MLD is coupled, the second accommodation portion 3500 may be isolated from the cavity 3400 by the inner wall 3200. Accordingly, it is possible to prevent a paste PST from leaking into the second accommodation portion 3500.

The inlet 3610 and the outlet 3620 may be disposed in the second top plate 3300. The inlet 3610 and the outlet 3620 may be passages penetrating upper and lower surfaces of the second top plate 3300. The inlet 3610 and the outlet 3620 may protrude from the second top plate 3300 in the third direction DR3. The protruding portions of the inlet 3610 and the outlet 3620 may be respectively coupled to a first coupling hole 2410 and a second coupling hole 2420 of the upper mold 2000.

The inlet 3610 may be a passage through which the paste PST is injected. The outlet 3620 may be a passage through which excess of the injected paste PST is discharged. The inlet 3610 and the outlet 3620 may be passages connecting the cavity 3400 and the outside, so that the paste PST can be injected into the cavity 3400 or be discharged from the cavity 3400.

In some embodiments, the inner mold 3000 may include a material having appropriate strength and elasticity so that the inner mold 3000 maintains its shape in normal times but the shape of the inner mold 3000 changes when the mold MLD is coupled. For example, the inner mold 3000 may include silicon, but is not necessarily limited thereto. Accordingly, even when a step is formed at the contact portion of the inner mold 3000, the shape of the inner mold 3000 changes to match the difference in the step, thereby increasing the effect of sealing the cavity 3400.

As illustrated in FIGS. 19 and 20, in the coupling the mold and the object together (operation S200), the upper mold 2000, the inner mold 3000, the object, and the lower mold 1000 may be arranged in order. The mold MLD may be assembled as the upper mold 2000, the inner mold 3000, and the lower mold 1000 are brought close to each other with the object interposed between them.

When the mold MLD is assembled, the object may be completely sealed by the mold MLD. For example, an upper surface 20a of the cover window 20 may contact the lower mold 1000, a side surface 20c of the cover window 20 may contact an inner surface of the second outer wall 3100, and a lower surface PCBb of a driving board PCB may contact a lower surface 3200a of the inner wall 3200. Accordingly, the cavity 3400 may be completely sealed by a lower surface 20b of the cover window 20, the inner surface of the second outer wall 3100, the lower surface of the second top plate 3300, the outer surface of the inner wall 3200 and the outer edge of the display driving module 10.

In the mold MLD, which is the display device manufacturing apparatus according to the current embodiment, and the display device manufacturing method S1 according to the current embodiment, since the lower surfaces of the inner walls 3200 contact a lower surface PCBb of the driving board PCB, damage caused by pressing of the display driving module 10 can be minimized. For example, since the lower surface of the inner wall 3200 does not contact the relatively weak cover panel 400 or cover spacer 500, but contacts the relatively strong driving board PCB, the damage caused by pressing the display driving module 10 can be minimized.

In the drawings, when the mold MLD is assembled, lower surfaces of the first outer walls 2100 of the upper mold 2000 contact an upper surface of the base 1100. However, the present disclosure is not necessarily limited thereto. When the mold MLD is assembled, the lower surfaces of the first outer walls 2100 of the upper mold 2000 may also not contact the upper surface of the base 1100.

In addition, in the drawings, when the mold MLD is assembled, lower surfaces of the second outer walls 3100 of the inner mold 3000 do not contact the upper surface of the base 1100 of the lower mold 1000. However, the present disclosure is not necessarily limited thereto. When the mold MLD is assembled, the lower surfaces of the second outer walls 3100 of the inner mold 3000 may also contact the upper surface of the base 1100 of the lower mold 1000.

As illustrated in FIG. 21, in the injecting the paste through the inlet (operation S300), paste PST may be injected into the cavity 3400 using a head HD.

The head HD may be an injection device that can inject liquid paste PST, such as an inkjet device or a dispenser device.

The paste PST may include liquid resin. For example, the paste PST may include, but is not necessarily limited to, optically clear resin in liquid form.

The paste PST may be discharged from the head HD and injected into the cavity 3400 through the inlet 3610. Since the cavity 3400 at least partially surrounds the display driving module 10 along the inner walls 3200, the paste PST injected into the cavity 3400 may move clockwise and counterclockwise to fill the entire cavity 3400.

In some embodiments, when the cavity 3400 is filled with an amount of paste PST that exceeds the volume of the cavity 3400, the excess paste PST may be discharged through the outlet 3620. The excess paste PST may remain in the inlet 3610 and the outlet 3620.

As illustrated in FIG. 22, in the forming the outer structure by curing the paste (operation S400), the paste PST may be cured through thermal curing or ultraviolet curing to form the outer structure 30.

In some embodiments, to thermally heat the paste PST, the mold MLD may further include heaters 4000. For example, the heaters 4000 may include a first heater 4100 disposed above the upper mold 2000 and a second heater 4200 disposed below the lower mold 1000. However, the present disclosure is not necessarily limited thereto, and a heater surrounding the entire mold MLD may also be provided to apply heat from all directions.

The excess paste PST remaining in the inlet 3610 and the outlet 3620 may form tips 30_T.

As illustrated in FIG. 23, in the disassembling the mold and the collecting of the object (operation S500), the lower mold 1000, the object, the inner mold 3000, and the upper mold 2000 may be decoupled and separated from each other. The object separated from the mold MLD may be collected to a separate room for further processing.

As illustrated in FIG. 24, in the removing of the tips of the object, the tips 30_T disposed on the outer structure 30 may be removed using a cutting device.

Although the tips 30_T overlap the outer structure 30 in the third direction DR3 in the drawing, the present disclosure is not necessarily limited thereto. In some embodiments, the tips 30_T might not overlap the outer structure 30 in the third direction DR3. In this case, the inlet 3610 and the outlet 3620 might not overlap the cavity 3400 in the third direction DR3. Accordingly, it is possible to prevent a step from being formed on a lower surface of the outer structure 30 when the tips 30_T are removed.

In concluding the detailed description, those skilled in the art will appreciate that many variations and modifications can be made to the embodiments described herein without substantially departing from the principles of the present disclosure.

What is claimed is:

1. A display device, comprising:
a cover window;
a display module disposed on the cover window and comprising a display panel;
a driving board disposed on the display module and connected to the display panel; and
an outer structure at least partially surrounding the display module and the driving board on the cover window,
wherein the outer structure is in contact with the driving board.

2. The display device of claim 1,
wherein an inner surface of the outer structure directly contacts a side surface of the driving board.

3. The display device of claim 2,
wherein a boundary of the inner surface of the outer structure coincides with a boundary of a side surface of the driving board.

4. The display device of claim 2,
wherein the outer structure covers at least a portion of a lower surface of the driving board, the lower surface being a surface of the driving board farthest from the cover window.

5. The display device of claim 4,
wherein the outer structure comprises:
a first portion that is in contact with the side surface of the driving board; and
a second portion protruding from the first portion and in contact with the lower surface of the driving board.

6. The display device of claim 1,
wherein the outer structure overlaps the display panel in a thickness direction of the display panel.

7. The display device of claim 6,
wherein the display module further comprises a cover spacer and/or a cover panel disposed between the display panel and the driving board.

8. The display device of claim 7,
wherein the outer structure overlaps the cover spacer and/or the cover panel in the thickness direction of the display panel.

9. The display device of claim 1,
further comprising a middle frame at least partially surrounding the display module,
wherein the outer structure is at least partially surrounded by the middle frame.

10. The display device of claim 9,
wherein the middle frame comprises a middle plate and a middle side wall disposed on a side surface of the middle plate, and
wherein the outer structure is at least partially surrounded by the middle side wall.

11. The display device of claim 10,
wherein the middle side wall comprises a first middle side wall connected to the middle plate and a second middle side wall connected to the first middle side wall,
wherein the first middle side wall is disposed under the outer structure, and
wherein the second middle side wall is disposed on an outside of the outer structure.

12. The display device of claim 11,
further comprising a first coupling disposed between the middle frame and the outer structure,
wherein the first coupling comprises:
a first coupling element disposed between the first middle side wall and the outer structure; and
a second coupling element disposed between the second middle side wall and the outer structure.

13. The display device of claim 1,
wherein the display panel comprises a main area, a bending area disposed on one side of the main area, and a sub-area disposed on one side of the bending area,
wherein the outer structure comprises:
a first portion disposed on an outside of the bending area; and
a second portion disposed on an inside of the bending area.

14. The display device of claim 13,
wherein the outer structure further comprises a third portion at least partially covering the sub-area of the display panel.

15. The display device of claim 14,
wherein the display module further comprises a bending protection layer disposed on an outside of the display panel in the bending area, and
wherein the bending protection layer extends to the sub-area.

16. The display device of claim 15,
wherein one end of the bending protection layer protrudes more inwardly than one end of the third portion.

17. An apparatus for manufacturing a display device, the display device comprising a display module and a driving board connected to the display module, the apparatus comprising:
an upper mold and a lower mold facing each other; and
an inner mold disposed between the upper mold and the lower mold,
wherein the inner mold comprises:
an outer wall;
an inner wall disposed inside the outer wall;
a cavity disposed between the outer wall and the inner wall; and
an accommodation portion disposed inside the inner wall,
wherein the inner wall is in contact with the driving board.

18. The display device of claim 17,
wherein a lower surface of the inner wall is in contact with a lower surface of the driving board.

19. A method of manufacturing a display device, the display device comprising a display module and a driving board connected to the display module, the method comprising:
coupling a mold to the display device;
injecting a paste through an inlet of the mold; and
forming an outer structure by curing the paste,
wherein the outer structure is in contact with the driving board.

20. The method of claim 19,
wherein an inner surface of the outer structure is in contact with a side surface of the driving board.
